(19) United States
(12) Patent Application Publication
(10) Pub. No.: US 2024/0363795 A1
(43) Pub. Date: Oct. 31, 2024

(54) SEMICONDUCTOR OPTICAL ELEMENT, MEASUREMENT DEVICE AND LIGHT SOURCE DEVICE USING SEMICONDUCTOR OPTICAL ELEMENT, AND METHOD FOR MANUFACTURING SEMICONDUCTOR OPTICAL ELEMENT

(71) Applicant: NICHIA CORPORATION, Anan-shi (JP)

(72) Inventor: Masahiko SANO, Yokohama-shi (JP)

(73) Assignee: NICHIA CORPORATION, Anan-shi (JP)

(21) Appl. No.: 18/644,418

(22) Filed: Apr. 24, 2024

(30) Foreign Application Priority Data
Apr. 28, 2023 (JP) 2023-075029

(51) Int. Cl. H01L 33/02; G01S 7/481; G01S 7/4863; H01L 33/26

(52) U.S. Cl. CPC H01L 33/025; G01S 7/4814; G01S 7/4863; H01L 33/26

(57) ABSTRACT

A semiconductor optical element includes a first indirect transition type semiconductor portion including a first conductivity type impurity at a first concentration, a second indirect transition type semiconductor portion including the first conductivity type impurity at a second concentration, a third indirect transition type semiconductor portion including a second conductivity type impurity at a third concentration, a fourth indirect transition type semiconductor portion including the second conductivity type impurity at a fourth concentration, and a fifth indirect transition type semiconductor portion including the second conductivity type impurity at a fifth concentration, in this order. The third indirect transition type semiconductor portion and the fourth indirect transition type semiconductor portion are in contact with each other. The first concentration is higher than the second concentration. The third concentration is higher than the fourth concentration. The fifth concentration is higher than the fourth concentration.

### CROSS-REFERENCE TO RELATED APPLICATIONS

The present application claims priority under 35 U.S.C. § 119 to Japanese Patent Application No. 2023-075029, filed Apr. 28, 2023, the contents of which are hereby incorporated by reference in their entirety.

### BACKGROUND

### 1. Technical Field

The present disclosure relates to a semiconductor optical element, a measurement device and a light source device using the semiconductor optical element, and a method for manufacturing a semiconductor optical element.

### 2. Description of Related Art

A light-emitting element such as a laser diode or a light-emitting diode is generally formed using a direct transition type semiconductor having high light-emission efficiency. On the other hand, an indirect transition type semiconductor such as silicon has low light-emission efficiency and is considered unsuitable as a light-emitting element. Many electronic devices are formed using silicon (Si), and a light-emitting element formed using an indirect transition type semiconductor is desired to be fabricated. A known light-emitting element uses an indirect transition type semiconductor and includes a high-concentration p-layer, a low-concentration p-layer, a p-n junction layer, a low-concentration n-layer, and a high-concentration n-layer layered in this order from the top (for example, see Japanese Patent Publication No. 2017-092075). This layered structure is designed to increase the carrier mobility by an i-layer with no added impurities being inserted into each layer.

### SUMMARY

Also in indirect transition type semiconductors, there is a demand for improvement in light-emission efficiency. According to one aspect of the present disclosure, there is provided a semiconductor optical element using an indirect transition type semiconductor and having high light-emission efficiency, and a method for manufacturing the semiconductor optical element.

A semiconductor optical element according to one embodiment of the present disclosure includes, in the following order: a first indirect transition type semiconductor portion including a first conductivity type impurity at a first concentration; a second indirect transition type semiconductor portion including the first conductivity type impurity at a second concentration; a third indirect transition type semiconductor portion including a second conductivity type impurity at a third concentration; a fourth indirect transition type semiconductor portion including the second conductivity type impurity at a fourth concentration; and a fifth indirect transition type semiconductor portion including the second conductivity type impurity at a fifth concentration. In the semiconductor optical element, the third indirect transition type semiconductor portion and the fourth indirect transition type semiconductor portion are in contact with each other, the first concentration is higher than the second concentration, the third concentration is higher than the fourth concentration, and the fifth concentration is higher than the fourth concentration.

A method for manufacturing a semiconductor optical element according to an embodiment of the present disclosure includes: preparing a first structure including a first indirect transition type semiconductor portion including a first conductivity type impurity at a first concentration, a second indirect transition type semiconductor portion including the first conductivity type impurity at a second concentration lower than the first concentration, the second indirect transition type semiconductor portion being provided on the first indirect transition type semiconductor portion, and a third indirect transition type semiconductor portion including a second conductivity type impurity at a third concentration, the third indirect transition type semiconductor portion being provided on the second indirect transition type semiconductor portion; preparing a second structure including a fourth indirect transition type semiconductor portion including the second conductivity type impurity at a fourth concentration and a fifth indirect transition type semiconductor portion including the second conductivity type impurity at a fifth concentration, the fourth concentration being lower than the third concentration and the fifth concentration, the fourth indirect transition type semiconductor portion being provided on the fifth indirect transition type semiconductor portion; and directly bonding the third indirect transition type semiconductor portion and the fourth indirect transition type semiconductor portion with the third indirect transition type semiconductor portion of the first structure and the fourth indirect transition type semiconductor portion of the second structure facing each other.

According to certain embodiments of the present disclosure, a semiconductor optical element using an indirect transition type semiconductor and having high light-emission efficiency and a method for manufacturing the semiconductor optical element may be achieved.

### BRIEF DESCRIPTION OF THE DRAWINGS

FIG. 1 illustrates an example of the cross-sectional configuration in a YZ plane of a semiconductor optical element according to an embodiment.

FIG. 2 illustrates an example of the cross-sectional configuration in an XZ plane orthogonal to a resonance direction.

FIG. 3 illustrates another example of the cross-sectional configuration in an XZ plane orthogonal to the resonance direction.

FIG. 4A illustrates an example of the cross-sectional configuration in a YZ plane aligned with the resonance direction.

FIG. 4B illustrates another example of the cross-sectional configuration in a YZ plane aligned with the resonance direction.

FIG. 5A is a schematic diagram illustrating a modified example of the semiconductor optical element.

FIG. 5B is a schematic diagram illustrating another modified example of the semiconductor optical element.

FIG. 5C is a schematic diagram illustrating another modified example of the semiconductor optical element.

FIG. 6A is a schematic diagram of a semiconductor optical element manufacturing process.

FIG. 6B is a schematic diagram of the semiconductor optical element manufacturing process.

FIG. 6C is a schematic diagram of the semiconductor optical element manufacturing process.

FIG. 6D is a schematic diagram of the semiconductor optical element manufacturing process.

FIG. 6E is a schematic diagram of the semiconductor optical element manufacturing process.

FIG. 6F is a schematic diagram of the semiconductor optical element manufacturing process.

FIG. 7 is a schematic diagram illustrating yet another modified example of the semiconductor optical element.

FIG. 8 is a schematic diagram of a light source device using the semiconductor optical element.

FIG. 9 is a schematic diagram of a measurement device using the semiconductor optical element.

### DETAILED DESCRIPTION

Hereinafter, embodiments for carrying out the present disclosure will be described with reference to the drawings. The following description is intended to embody technical concepts of the present disclosure, and the present disclosure is not limited to the following unless specifically stated. In drawings, members having identical functions may be denoted by the same reference characters. In view of the ease of explanation or understanding of the points of view, the embodiments may be illustrated separately for convenience, but the partial substitutions or combinations of the configurations illustrated in different embodiments and examples are possible. In the embodiments described later, differences from the embodiment described before will be mainly described, and redundant descriptions of similarities with the embodiment described before may be omitted. The sizes, positional relationship, and the like of members illustrated in the drawings may be exaggerated to clarify explanation.

An indirect transition type semiconductor such as silicon has been considered unsuitable as a light-emitting material. On the other hand, in recent years, a technique has been proposed for causing an indirect transition type semiconductor to emit light by using a dressed photon, which is a type of near-field light generated in the vicinity of a substance having a nanoscale dimension, or a dressed photon phonon (DPP), which is a coupled of a dressed photon and a coherent phonon. The inventor has conducted studies to cause an indirect transition type semiconductor to emit light. For example, in M. Nedeljkovic et al., IEEE Photon. J. 3 (6), 1171-1180 (2011), it is proposed that silicon has an absorption coefficient rate of change Δα of 8.88×10⁻²¹Nₑ^{1.167}+5.84×10⁻²⁰Nₕ^{1.109} and a refractive index rate of change Δn of −5.40×10⁻²²Nₑ^{1.011}−1.53× 10⁻¹⁸Nₕ^{0.838} at a wavelength of 1550 nm. Nₑ is the free electron density, and Nₕ is the free hole density. This means that the absorption coefficient increases and the refractive index decreases with higher impurity concentrations. The inventor has focused on this and has come up with the idea of a configuration for improving the light-emission efficiency of an indirect transition type semiconductor by forming an optical confinement structure.

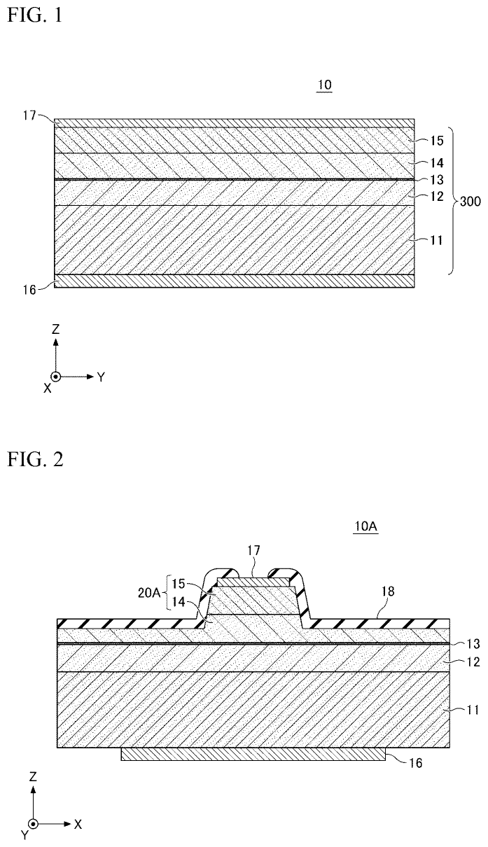

FIG. 1 is a schematic diagram of a semiconductor optical element 10 of an embodiment. The semiconductor optical element 10 includes a first indirect transition type semiconductor portion 11 including a first conductivity type impurity at a first concentration, a second indirect transition type semiconductor portion 12 including the first conductivity type impurity at a second concentration, a third indirect transition type semiconductor portion 13 including a second conductivity type impurity at a third concentration, a fourth indirect transition type semiconductor portion 14 including the second conductivity type impurity at a fourth concentration, and a fifth indirect transition type semiconductor portion 15 including the second conductivity type impurity at a fifth concentration, in this order. The third indirect transition type semiconductor portion 13 and the fourth indirect transition type semiconductor portion 14 are in contact with each other. The first concentration is higher than the second concentration. The third concentration is higher than the fourth concentration. The fifth concentration is higher than the fourth concentration. In this manner, an optical confinement structure can be formed with the first indirect transition type semiconductor portion 11 and the fifth indirect transition type semiconductor portion 15 as cladding and the second indirect transition type semiconductor portion 12, the third indirect transition type semiconductor portion 13, and the fourth indirect transition type semiconductor portion 14 as a core. With this optical confinement structure, light can be amplified, and the semiconductor optical element can efficiently emit light.

The first indirect transition type semiconductor portion 11, the second indirect transition type semiconductor portion 12, the third indirect transition type semiconductor portion 13, the fourth indirect transition type semiconductor portion 14, and the fifth indirect transition type semiconductor portion 15 form a layered structure 300. Here, the term “indirect transition type semiconductor portion” is intended to include a case in which each portion is a layer and a case in which each portion is a substrate. Si, Ge, Si—Ge, diamond (C), or the like may be used for the materials of the indirect transition type semiconductor portions. One of the first conductivity type and the second conductivity type is n-type, and the other is p-type. In the example in FIG. 1, the first conductivity type is n-type, and the second conductivity type is p-type.

The first indirect transition type semiconductor portion 11 includes the first conductivity type impurity at the first concentration. The first conductivity type impurity may be, for example, an n-type impurity, such as phosphorus (P), arsenic (As), or antimony (Sb), that forms a donor level with respect to the indirect transition type semiconductor material to be used. The first concentration is a concentration in a range from 1.0×10¹⁹ cm⁻³ to 5.0×10¹⁹ cm⁻³, for example. The first indirect transition type semiconductor portion 11 may be an indirect transition type semiconductor substrate including an n-type impurity at the first concentration. In particular, the first indirect transition type semiconductor portion 11 may be a Si substrate including an n-type impurity.

The second indirect transition type semiconductor portion 12 is provided on the first indirect transition type semiconductor portion 11 and includes the first conductivity type impurity at the second concentration. The second indirect transition type semiconductor portion 12 includes an n-type impurity at a concentration lower than that of the first indirect transition type semiconductor portion 11. Thus, the refractive index of the second indirect transition type semiconductor portion 12 can be made higher than the refractive index of the first indirect transition type semiconductor portion 11. The second concentration is a concentration in a range from 1.0×10¹⁶ cm⁻³ to 5.0×10¹⁶ cm⁻³, for example.

The third indirect transition type semiconductor portion 13 is provided on the second indirect transition type semiconductor portion 12 and includes the second conductivity type impurity at the third concentration. The second conductivity type impurity may be a p-type impurity such as boron (B), aluminum (Al), or gallium (Ga). The third concentration is higher than the fourth concentration described below. Accordingly, the second conductivity type impurity, which contributes to light emission, can be increased. The third concentration is a concentration in a range from 1.0×10¹⁷ cm⁻³ to 5.0×10¹⁹ cm⁻³, for example. The p-type impurity is included in an unactivated state as will be described later.

The fourth indirect transition type semiconductor portion 14 is provided on the third indirect transition type semiconductor portion 13. The third indirect transition type semiconductor portion 13 and the fourth indirect transition type semiconductor portion 14 are in contact with each other. The fourth indirect transition type semiconductor portion 14 includes a p-type impurity that forms an acceptor level with respect to the indirect transition type semiconductor material to be used, at the fourth concentration lower than the third concentration. The p-type impurity concentration (fourth concentration) of the fourth indirect transition type semiconductor portion 14 is in a range from 1.0×10¹⁶ cm⁻³ to 5.0×10¹⁶ cm⁻³, for example. The third concentration is in a range from 10 times to 1000 times the fourth concentration. Because the p-type impurity of the third indirect transition type semiconductor portion 13 is included at a higher concentration than the p-type impurity of the fourth indirect transition type semiconductor portion 14, the second conductivity type impurity, which contributes to light emission, can be increased in the third indirect transition type semiconductor portion 13.

The fifth indirect transition type semiconductor portion 15 is provided on the fourth indirect transition type semiconductor portion 14 and includes a p-type impurity at the fifth concentration higher than the fourth concentration. Thus, the refractive index of the fifth indirect transition type semiconductor portion 15 can be made lower than the refractive index of the fourth indirect transition type semiconductor portion 14. The p-type impurity concentration of the fifth indirect transition type semiconductor portion 15 is in a range from 1.0×10¹⁹ cm⁻³ to 5.0×10¹⁹ cm⁻³, for example.

The first indirect transition type semiconductor portion 11 has a lower electrical resistivity and a lower refractive index than the second indirect transition type semiconductor portion 12. The fifth indirect transition type semiconductor portion 15 has a lower electrical resistivity and a lower refractive index than the fourth indirect transition type semiconductor portion 14. The first indirect transition type semiconductor portion 11 and the fifth indirect transition type semiconductor portion 15 function as cladding for the second indirect transition type semiconductor portion 12, the third indirect transition type semiconductor portion 13, and the fourth indirect transition type semiconductor portion 14.

The second indirect transition type semiconductor portion 12, the third indirect transition type semiconductor portion 13, and the fourth indirect transition type semiconductor portion 14 as a whole have a higher electrical resistivity and a higher refractive index than the first indirect transition type semiconductor portion 11 and the fifth indirect transition type semiconductor portion 15 and function as the core. Thus, the semiconductor optical element 10 including the first indirect transition type semiconductor portion 11, the second indirect transition type semiconductor portion 12, the third indirect transition type semiconductor portion 13, the fourth indirect transition type semiconductor portion 14, and the fifth indirect transition type semiconductor portion 15 has an optical confinement structure formed by the core and the cladding.

Because an indirect transition type semiconductor doped with an n-type impurity is less likely to have a difference in the refractive index than one doped with a p-type impurity, the n-type impurity concentration of the first indirect transition type semiconductor portion 11 may be set higher than the p-type impurity concentration of the fifth indirect transition type semiconductor portion 15. Accordingly, the difference in the refractive index between the core and the cladding can be increased, and light can be efficiently confined in the core. In a similar manner, the n-type impurity concentration of the second indirect transition type semiconductor portion 12 may be set higher than the p-type impurity concentration of the fourth indirect transition type semiconductor portion 14.

The reason the third indirect transition type semiconductor portion 13 including the p-type impurity at a higher concentration than the p-type impurity concentration of the fourth indirect transition type semiconductor portion 14 is provided between the n-type second indirect transition type semiconductor portion 12 and the p-type fourth indirect transition type semiconductor portion 14 is to increase the second conductivity type impurity, which contributes to light emission. This light emission may utilize DPPs, for example. The p-type impurity may be used as a nanomaterial that is a DPP generation source. As described above, a DPP is a dressed photon, which is a coupling of a photon and an electron/hole pair, being further coupled with a coherent phonon with aligned vibration phases. By utilizing DPPs, an energy level derived from the DPPs is formed between the conduction band minimum and the valence band maximum. This promotes light emission on the side of wavelengths longer than the wavelength determined by the band gap of Si.

The thickness of the third indirect transition type semiconductor portion 13 is preferably smaller than the thickness of the fourth indirect transition type semiconductor portion 14. The third indirect transition type semiconductor portion 13 can be used as a DPP generation source, and can also serve as a light absorption source. Because the third indirect transition type semiconductor portion 13 is smaller than the fourth indirect transition type semiconductor portion 14, the absorption of light can be reduced and the extraction efficiency of light from a semiconductor optical element 10A can be improved. The thickness of the third indirect transition type semiconductor portion 13 is in a range from 10 nm to 1500 nm. When an electric current is injected into the semiconductor optical element 10 illustrated in FIG. 1 with an electrode 16 provided on the back surface of the first indirect transition type semiconductor portion 11 and an electrode 17 provided on the upper surface of the fifth indirect transition type semiconductor portion 15, light having a peak wavelength in a range from 1100 nm to 4000 nm, from near-infrared to mid-infrared regions is emitted by the effect of DPPs as described above. The peak wavelength may be in a range from 1300 nm to 2000 nm. The light-emission wavelength utilizing DPPs is determined by the spacing between atoms (nanoparticles) that are DPP generation sources. A concentration of B of when light is emitted at a peak wavelength in a range from 1100 nm to 4000 nm is in a range from 1.0×10¹⁶ cm⁻³ to 5.0×10¹⁹ cm⁻³. The wavelength shifts to the long wavelength side when the concentration of B is lower, that is, when the spacing between localized B atoms is wider. For example, with a B concentration of about 1.0×10¹⁹ cm⁻³, light with a peak wavelength around 1300 nm is emitted.

FIG. 2 illustrates an example of the cross-sectional configuration in an XZ plane orthogonal to the resonance direction of the semiconductor optical element 10A. In the coordinate system in FIG. 2, the resonance direction of the semiconductor optical element 10A is defined as the Y direction. The semiconductor optical element 10A has the same layered structure as the layered structure 300 illustrated in FIG. 1 and includes a ridge 20A that confines light in the horizontal direction (X direction). The ridge 20A is formed of at least a part of the fourth indirect transition type semiconductor portion 14 and the fifth indirect transition type semiconductor portion 15, and the third indirect transition type semiconductor portion 13 is located below the ridge 20A. This makes it possible to control the difference in refractive index in the horizontal direction, and thus to control the transverse mode. The width of the ridge 20A in the X direction may increase from the fifth indirect transition type semiconductor portion 15 toward the first indirect transition type semiconductor portion 11. This makes it easy to form a protective film provided on the lateral surface of the ridge 20A.

The n-side electrode 16 is provided on the back surface of the first indirect transition type semiconductor portion 11, and the p-side electrode 17 is provided on the upper surface of the ridge 20A. A protective film 18 covers the lateral surface of the ridge 20A and the top surface of the fourth indirect transition type semiconductor portion 14 with the top surface of the electrode 17 exposed.

When a current is injected into the semiconductor optical element 10A using the electrodes 16 and 17, light is generated at the interface between the n-type second indirect transition type semiconductor portion 12 and the p-type third indirect transition type semiconductor portion 13 having a higher impurity concentration than the fourth indirect transition type semiconductor portion 14 by recoupling via DPPs. The light is confined in the vertical direction (Z direction) by the first indirect transition type semiconductor portion 11 and the fifth indirect transition type semiconductor portion 15, and is confined in the horizontal direction in the optical waveguide formed according to the difference in refractive index formed by the ridge 20A. In the fourth indirect transition type semiconductor portion 14, the effective refractive index perceived by light increases at the portion where the thickness is increased by the ridge 20A, and light is confined in the X direction in or near the active layer immediately below the ridge 20A. This configuration may be referred to as an “effective refractive index waveguide type.”

The configuration in FIG. 2 has an advantage in that the amount of etching for forming the ridge 20A is small and the flatness of the lateral surface of the ridge 20A is easily ensured.

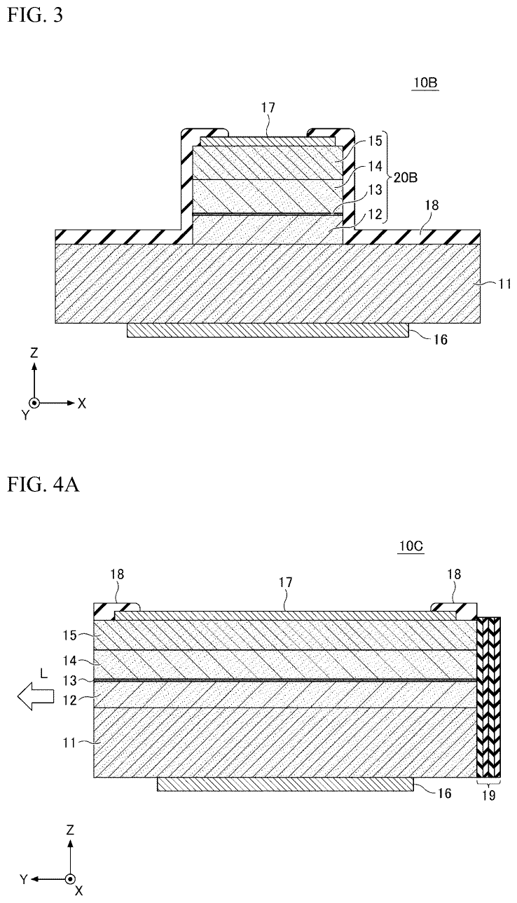

FIG. 3 illustrates another example of the cross-sectional configuration in an XZ plane orthogonal to the resonance direction of a semiconductor optical element 10B. In the coordinate system in FIG. 3, the resonance direction of the semiconductor optical element 10B is defined as the Y direction. The semiconductor optical element 10B has the same layered structure as the layered structure 300 illustrated in FIG. 1 and includes a ridge 20B that confines light in the horizontal direction (X direction). The ridge 20B is formed of the second indirect transition type semiconductor portion 12, the third indirect transition type semiconductor portion 13, the fourth indirect transition type semiconductor portion 14, and the fifth indirect transition type semiconductor portion 15. The interface between the n-type second indirect transition type semiconductor portion 12 and the p-type third indirect transition type semiconductor portion 13 having a higher concentration than the fourth indirect transition type semiconductor portion 14 is located inside the ridge 20B.

The n-side electrode 16 is provided on the back surface of the first indirect transition type semiconductor portion 11, and the p-side electrode 17 is provided on the upper surface of the ridge 20B. A protective film 18 covers the lateral surface of the ridge 20B and the top surface of the first indirect transition type semiconductor portion 11 with the top surface of the electrode 17 exposed.

In the configuration illustrated in FIG. 3, the light generated by the recoupling via DPPs at the interface between the second indirect transition type semiconductor portion 12 and the third indirect transition type semiconductor portion 13 is confined in the ridge 20B in both the horizontal direction (X direction) and the vertical direction (Z direction) and propagates in the resonance direction (Y direction). This configuration may be referred to as a “perfect refractive index waveguide type.” This configuration has an advantage in that optical loss can be reduced.

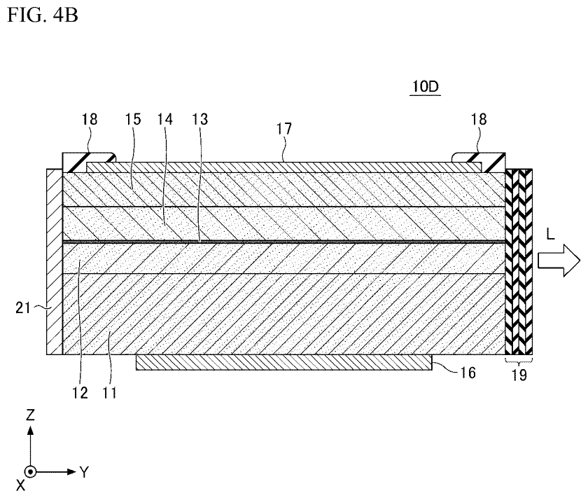

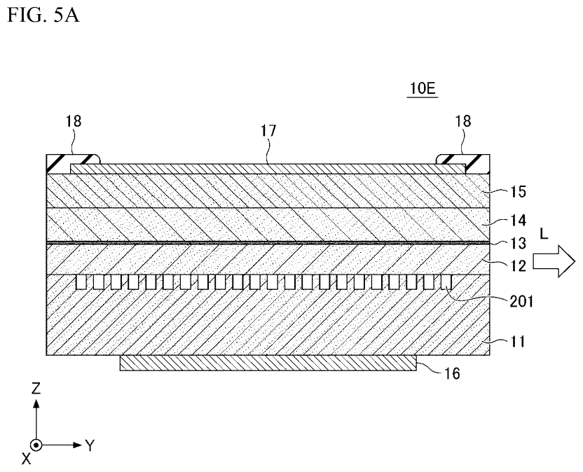

FIG. 4A illustrates an example of the cross-sectional configuration in a YZ plane along the resonance direction (Y direction) of a semiconductor optical element 10C. The semiconductor optical element 10C has the same layered structure as the layered structure 300 of the semiconductor optical element 10 illustrated in FIG. 1 and includes a dielectric multilayer mirror 19 at one end surface orthogonal to the resonance direction (Y direction). For example, when the reflectance of the dielectric multilayer mirror 19 is higher than the reflectance of the end surface opposite the end surface where the dielectric multilayer mirror 19 is provided, light Lis emitted in the direction of the arrow. In the dielectric multilayer mirror 19, layers having a high refractive index and layers having a low refractive index are alternately arranged. The film thicknesses of the layers are set such that light reflected at the interface between the layers is strengthened by interference, and the layers have wavelength selectivity. The combination of materials of the dielectric multilayer mirror may be, for example, SiO₂ and TiO₂, SiO₂ and Si, or SiO₂ and SiN.

The dielectric multilayer mirror 19 may be formed by a physical growth method such as vacuum deposition or sputtering or may be formed by a chemical vapor deposition (CVD) method or the like. The end surface opposite the dielectric multilayer mirror 19 may be a cleavage plane. In a case in which the first indirect transition type semiconductor portion 11 to the fifth indirect transition type semiconductor portion 15 are silicon single crystals or silicon epitaxial growth films, the (110) plane or the (111) plane is the cleavage plane. The cleavage plane is used as a reflective surface.

FIG. 4B illustrates another example of the cross-sectional configuration in a YZ plane along the resonance direction (Y direction) of a semiconductor optical element 10D. The semiconductor optical element 10D has the same layered structure as the layered structure 300 of the semiconductor optical element 10 illustrated in FIG. 1 and includes the dielectric multilayer mirror 19 at one end surface orthogonal to the resonance direction (Y direction) and a highly reflective film 21 at the other end surface. The highly reflective film 21 may be a dielectric multilayer mirror. The highly reflective film 21 has a reflectance of 95% or greater, preferably 98% or greater, more preferably close to 100%. In the example illustrated in FIG. 4B, the reflectance of the highly reflective film 21 is higher than the reflectance of the dielectric multilayer mirror 19. In this case, the light Lis taken out from the dielectric multilayer mirror 19 side. The end surface where the highly reflective film 21 is formed may be a cleavage plane or an etching plane. In the case of an etching plane, the highly reflective film 21 may be formed after polishing.

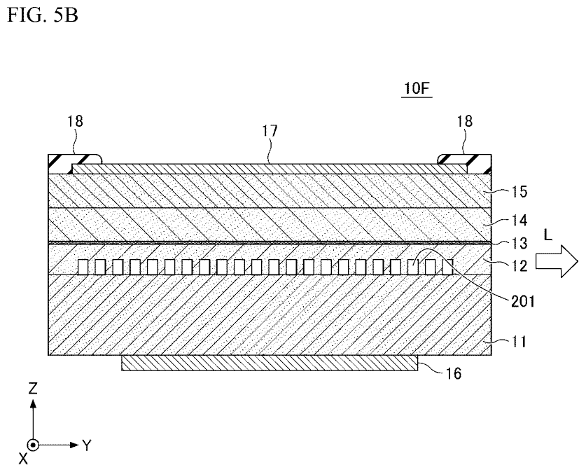

FIG. 5A is a schematic diagram illustrating a semiconductor optical element 10E, which is a modified example of the semiconductor optical element 10. At least one of the first indirect transition type semiconductor portion 11 and the second indirect transition type semiconductor portion 12 of the semiconductor optical element 10 includes a plurality of grooves or a plurality of voids provided at intervals. The plurality of grooves or the plurality of voids are arranged in at least a first direction, and the first direction is at least aligned with the resonance direction (Y direction) of the semiconductor optical element 10. In the semiconductor optical element 10E illustrated in FIG. 5A, a plurality of periodic grooves or voids (hereinafter simply referred to as “grooves 201”) are formed in the first indirect transition type semiconductor portion 11.

Air may be inside the grooves 201 or the grooves 201 may be filled with a material having a refractive index lower than that of the first indirect transition type semiconductor portion 11. A diffraction grating is formed by the grooves 201 arranged at intervals along the resonance direction (Y direction). A periodic structure in which a refractive index is spatially modulated at certain intervals is formed at an interface between the first indirect transition type semiconductor portion 11 functioning as the cladding and the second indirect transition type semiconductor portion 12 functioning as a part of the core. The light with the wavelength selected by the diffraction grating returns into the core and intensifies to cause laser oscillation at the wavelength. The interval of the grooves 201 may be (i) λ/(2× n_{eff}) or (ii) λ/n_{eff}, where λ is the wavelength in a vacuum and n_{eff} is the effective refractive index. In other words, when the interval of the grooves 201 is determined, oscillation occurs at a wavelength that satisfies the relationship (i) or (ii). When the interval of the grooves 201 is (i) and the direction of the interval is one-dimensional (Y direction), the laser light oscillates in the Y direction. Also, when the interval of the grooves 201 is (ii) and the direction of the interval is two-dimensional (X direction and Y direction), the laser light oscillates in the Z direction.

FIG. 5B is a schematic diagram illustrating a semiconductor optical element 10F, which is a modified example of the semiconductor optical element 10. The semiconductor optical element 10F is different from the semiconductor optical element 10E in that the plurality of periodic grooves 201 are formed in the second indirect transition type semiconductor portion 12. Because the grooves 201 are formed in the second indirect transition type semiconductor portion 12 closer to the third indirect transition type semiconductor portion 13 than the first indirect transition type semiconductor portion 11 is, the periodic change of the refractive index is easily perceived by light, and the wavelength selectivity can be enhanced. The other matters are the same as those described with reference to FIG. 5A.

FIG. 5C is a schematic diagram illustrating a semiconductor optical element 10G, which is a modified example of the semiconductor optical element 10. The semiconductor optical element 10G is different from the semiconductor optical element 10E in that the plurality of periodic grooves 201 are formed across the first indirect transition type semiconductor portion 11 and the second indirect transition type semiconductor portion 12. The other matters are the same. A diffraction grating is formed by the grooves 201 arranged at intervals along the resonance direction (Y direction). Thus, light can be efficiently confined in the second indirect transition type semiconductor portion 12 more than in the first indirect transition type semiconductor portion 11. In addition, the absorption of light by the first indirect transition type semiconductor portion 11 can be reduced. Because the grooves 201 are also formed in the second indirect transition type semiconductor portion 12 closer to the third indirect transition type semiconductor portion 13 than the first indirect transition type semiconductor portion 11 is, the periodic change of the refractive index is easily perceived by light, and the wavelength selectivity can be enhanced.

The semiconductor optical elements 10A to 10G according to the embodiments described above can be used in, for example, a semiconductor laser element, a semiconductor light amplifier, or a master oscillator power amplifier (MOPA).

### Method for Manufacturing Semiconductor Optical Element

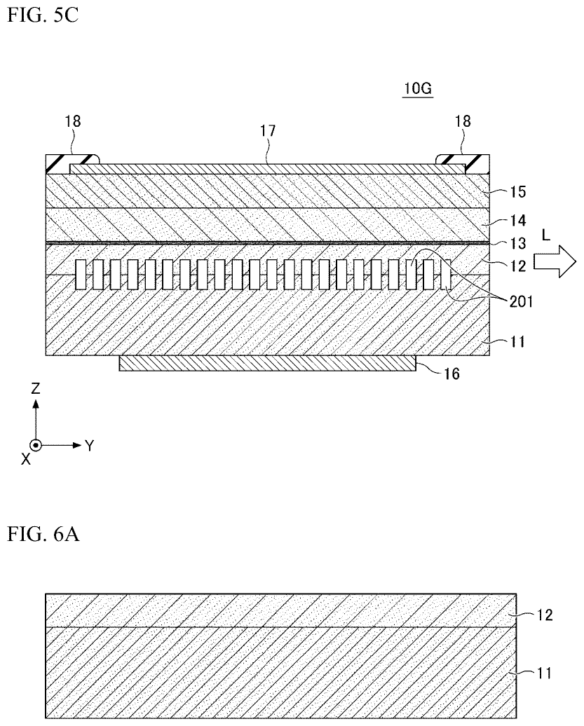

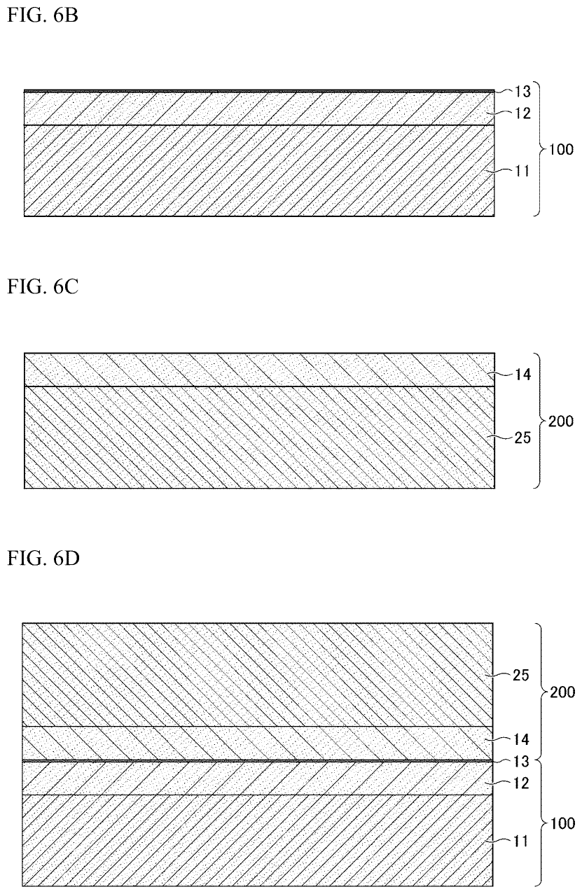

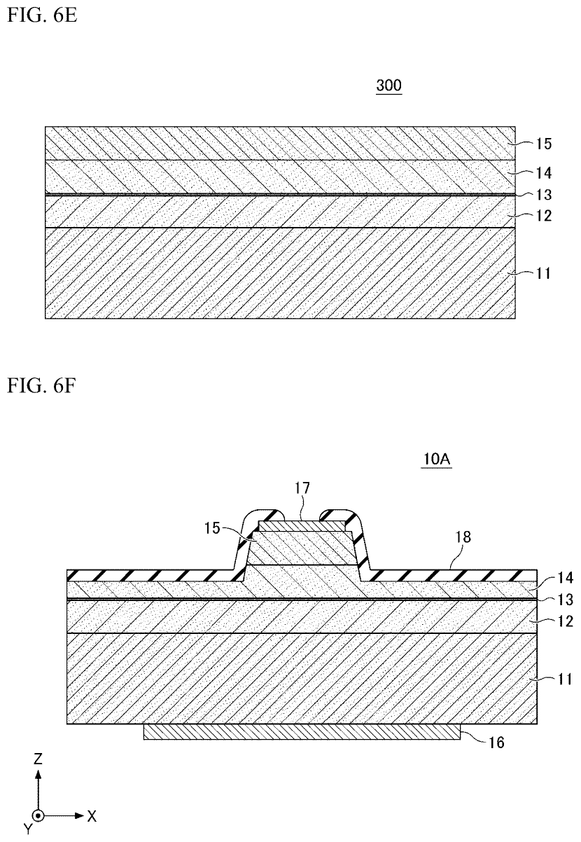

FIGS. 6A to 6F are schematic diagrams of a semiconductor optical element manufacturing process. The process up to forming the layered structure 300 including the first indirect transition type semiconductor portion 11, the second indirect transition type semiconductor portion 12, the third indirect transition type semiconductor portion 13, the fourth indirect transition type semiconductor portion 14, and the fifth indirect transition type semiconductor portion 15 is the same for the semiconductor optical elements 10A to 10G. An element having the cross-sectional shape of the semiconductor optical element 10A illustrated in FIG. 2 as the cross-sectional shape in the XZ plane orthogonal to the resonance (Y) direction is manufactured.

The process for manufacturing a semiconductor optical element includes preparing a first structure including a first indirect transition type semiconductor portion including a first conductivity type impurity at a first concentration, a second indirect transition type semiconductor portion including the first conductivity type impurity at a second concentration lower than the first concentration, the second indirect transition type semiconductor portion being provided on the first indirect transition type semiconductor portion, and a third indirect transition type semiconductor portion including a second conductivity type impurity at a third concentration, the third indirect transition type semiconductor portion being provided on the second indirect transition type semiconductor portion; preparing a second structure including a fifth indirect transition type semiconductor portion including the second conductivity type impurity at a fifth concentration and a fourth indirect transition type semiconductor portion including the second conductivity type impurity at a fourth concentration lower than the third concentration and the fifth concentration, the fourth indirect transition type semiconductor portion being provided on the fifth indirect transition type semiconductor portion; and directly bonding the third indirect transition type semiconductor portion and the fourth indirect transition type semiconductor portion, with the third indirect transition type semiconductor portion of the first structure and the fourth indirect transition type semiconductor portion of the second structure facing each other. In this manner, an optical confinement structure is formed, and thus a semiconductor optical element that can efficiently emit light can be obtained.

### Process of Preparing First Structure

First, a first structure 100 is prepared. The first structure 100 includes the first indirect transition type semiconductor portion 11 including the first conductivity type impurity at the first concentration, the second indirect transition type semiconductor portion 12 including the first conductivity type impurity at the second concentration lower than the first concentration, the second indirect transition type semiconductor portion 12 being provided on the first indirect transition type semiconductor portion 11, and the third indirect transition type semiconductor portion 13 including the second conductivity type impurity at the third concentration, the third indirect transition type semiconductor portion 13 being provided on the second indirect transition type semiconductor portion 12. The first structure 100 can be formed by the procedure as described below with reference to FIGS. 6A and 6B.

First, as illustrated in FIG. 6A, the second indirect transition type semiconductor portion 12 is formed on the first indirect transition type semiconductor portion 11. The first indirect transition type semiconductor portion 11 includes the first conductivity type impurity at the first concentration. The first concentration is in a range from 1.0×10¹⁹ cm⁻³ to 5.0×10¹⁹ cm⁻³, for example. The first indirect transition type semiconductor portion 11 may be, for example, an indirect transition type semiconductor substrate or an indirect transition type semiconductor layer and is preferably an indirect transition type semiconductor substrate. The indirect transition type semiconductor substrate is formed by, for example, the Czochralski (CZ) method or a floating zone melting method (FZ method). The first conductivity type impurity may be introduced by ion implantation. After the ion implantation, thermal annealing may be performed to recover damage caused by the ion implantation. The indirect transition type semiconductor layer may be formed by, for example, a chemical vapor deposition (CVD) method or a molecular beam epitaxy (MBE) method. The thickness of the first indirect transition type semiconductor portion 11 is, for example, in a range from 300 μm to 600 μm.

The second indirect transition type semiconductor portion 12 includes the first conductivity type impurity at the second concentration. The second concentration is lower than the first concentration. The second concentration is in a range from 1.0×10¹⁶ cm⁻³ to 5.0×10¹⁶ cm⁻³, for example. As the second indirect transition type semiconductor portion 12, an indirect transition type semiconductor substrate may be bonded to the first indirect transition type semiconductor portion 11, or an indirect transition type semiconductor layer may be formed. Preferably, the second indirect transition type semiconductor portion 12 is an indirect transition type semiconductor layer. Because forming a part of the core of the semiconductor optical element, the second indirect transition type semiconductor portion 12 is thinner than the first indirect transition type semiconductor portion 11. Thus, it is easier to control the thickness when the indirect transition type semiconductor layer is formed as the second indirect transition type semiconductor portion 12. The second indirect transition type semiconductor portion may be formed by a CVD method or an MBE method. The thickness of the second indirect transition type semiconductor portion 12 is, for example, in a range from 1 μm to 3 μm.

Next, as illustrated in FIG. 6B, the third indirect transition type semiconductor portion 13 including the second conductivity type impurity at the third concentration is formed on the second indirect transition type semiconductor portion 12. The third concentration is in a range from 1.0×10¹⁷ cm⁻³ to 5.0×10¹⁹ cm⁻³, for example. The third indirect transition type semiconductor portion 13 is formed by implanting ions into the surface of the second indirect transition type semiconductor portion 12 opposite the surface that is in contact with the first indirect transition type semiconductor portion 11. The acceleration energy during the ion implantation may be, for example, in a range from 10 keV to 1000 keV. The implanted ions can penetrate from the top surface of the second indirect transition type semiconductor portion 12 to a depth of about 1500 nm or less. For example, by implanting B ions, a p-type Si layer is formed on the top surface of the second indirect transition type semiconductor portion 12. For example, a p-type Si layer having a thickness ranging from 40 nm to 60 nm is formed with an implantation energy of 10 keV. The B ion concentration of the p-type Si layer is, for example, 1.0×10¹⁹ cm⁻³.

Via such ion implantation, the first structure 100 including the first indirect transition type semiconductor portion 11, the second indirect transition type semiconductor portion 12 having a lower impurity concentration than the first indirect transition type semiconductor portion 11, and the third indirect transition type semiconductor portion 13 including B at a higher impurity concentration than the second indirect transition type semiconductor portion 12 is obtained.

### Process of Obtaining Second Structure

Subsequently, a second structure 200 is prepared. The second structure 200 includes a fifth indirect transition type semiconductor portion 25 including the second conductivity type impurity at the fifth concentration and the fourth indirect transition type semiconductor portion 14 including the second conductivity type impurity at the fourth concentration, the fourth indirect transition type semiconductor portion 14 being provided on the fifth indirect transition type semiconductor portion 25. The fourth concentration is lower than the third concentration and the fifth concentration.

First, as illustrated in FIG. 6C, the fourth indirect transition type semiconductor portion 14 is formed on the fifth indirect transition type semiconductor portion 25. The fifth indirect transition type semiconductor portion 25 includes the second conductivity type impurity at the fifth concentration. The fifth concentration is in a range from 1.0×10¹⁸ cm⁻³ to 5.0×10¹⁹ cm⁻³, for example. The fifth indirect transition type semiconductor portion 25 may be an indirect transition type semiconductor substrate or an indirect transition type semiconductor layer. The fifth indirect transition type semiconductor portion 25 is preferably an indirect transition type semiconductor substrate. The fifth indirect transition type semiconductor portion 25 may be formed by a CZ method, an FZ method, a CVD method, an MBE method, or the like. The thickness of the fifth indirect transition type semiconductor portion is, for example, in a range from 300 μm to 600 μm.

The fourth indirect transition type semiconductor portion 14 includes the second conductivity type impurity at the fourth concentration. The fourth concentration is lower than the third concentration and the fifth concentration. The fourth concentration is in a range from 1.0×10¹⁶ cm⁻³ to 1.0×10¹⁷ cm⁻³, for example. As the fourth indirect transition type semiconductor portion 14, an indirect transition type semiconductor substrate may be bonded to the fifth indirect transition type semiconductor portion 25, or an indirect transition type semiconductor layer. The fourth indirect transition type semiconductor portion 14 is preferably an indirect transition type semiconductor layer. Because forming a part of the core of the semiconductor optical element, the fourth indirect transition type semiconductor portion 14 is thinner than the fifth indirect transition type semiconductor portion 25. Thus, it is easier to control the thickness when the indirect transition type semiconductor layer is formed as the fourth indirect transition type semiconductor portion 14. The fourth indirect transition type semiconductor portion may be formed by a CVD method or an MBE method. The thickness of the fourth indirect transition type semiconductor portion 14 may be, for example, in a range from 1 μm to 3 μm. The order of the processes illustrated in FIGS. 6B and 6C may be reversed, or the processes may be performed simultaneously.

### Process of Direct Bonding

Subsequently, as illustrated in FIG. 6D, the third indirect transition type semiconductor portion 13 of the first structure 100 and the fourth indirect transition type semiconductor portion 14 of the second structure 200 are made to face each other, and the first structure 100 and the second structure 200 are combined by being directly bonded together. Thus, the third indirect transition type semiconductor portion 13 including the second conductivity type impurity at a higher concentration than the fourth indirect transition type semiconductor portion 14 is provided between the second indirect transition type semiconductor portion 12 of the first conductivity type and the fourth indirect transition type semiconductor portion 14 of the second conductivity type.

To combine the first structure 100 and the second structure 200, the top surface of the third indirect transition type semiconductor portion 13 and the top surface of the fourth indirect transition type semiconductor portion 14 are directly bonded without intentionally applying heat. In this case, diffusion of the second conductivity type impurity from the third indirect transition type semiconductor portion 13 to the fourth indirect transition type semiconductor portion 14 hardly occurs. Thus, the second conductivity type impurity included in the third indirect transition type semiconductor portion 13 does not have a stable distribution due to heat, and the second conductivity type impurity, which contributes to light emission, is less likely to decrease. Because the impurity concentration of the third indirect transition type semiconductor portion 13 is higher than the impurity concentrations of the second indirect transition type semiconductor portion 12 and the fourth indirect transition type semiconductor portion 14, the proportion of the impurity that contributes to light emission can be increased. By forming an optical waveguide and a resonator, described below, the generated light can be amplified to increase the light-emission efficiency.

“Direct bonding” refers to a method of bonding without disposing an intermediate member such as an adhesive. Direct bonding may be, for example, surface activated bonding. Surface activated bonding is a method in which surfaces to be bonded are cleaned in a vacuum to obtain bonding surfaces, and then the bonding surfaces are brought into contact with each other in a vacuum and bonded. Here, the objects to be bonded are the third indirect transition type semiconductor portion 13 and the fourth indirect transition type semiconductor portion 14. For example, a high-speed ion beam is emitted to the bonding surface planarized to have a surface roughness (Ra) equal to or less than 1 nm to obtain a bonding surface. “Without applying heat” means that thermal annealing and DPP annealing are not performed intentionally. The temperature in bonding may be, for example, in a range from 0° C. to 300° C., and preferably in a range from 0° C. to 100° C. The temperature of thermal annealing usually refers to 800° C. or higher. DPP annealing is a method for applying a forward current to the first structure 100 while irradiating the first structure 100 with light having a predetermined wavelength. This method may be performed when utilizing dressed photon phonons.

From the viewpoint of directly bonding the first structure 100 and the second structure 200 together, it is desirable that the surface region (first region) of the third indirect transition type semiconductor portion 13 of the first structure 100 before combination has an irregular atomic arrangement such as an amorphous arrangement. A region (second region) other than the surface region of the third indirect transition type semiconductor portion 13 may be amorphous or crystalline, but it is desirable that the crystal arrangement of the first region is more irregular than that of the second region.

Similarly, it is desirable that the surface region (third region) of the fourth indirect transition type semiconductor portion 14 of the second structure 200 before combination has an irregular atomic arrangement such as an amorphous arrangement. A region (fourth region) other than the surface region of the fourth indirect transition type semiconductor portion 14 may be amorphous or crystalline, but it is desirable that the crystal arrangement of the third region is more irregular than that of the fourth region. Via the combining process, the first region having an irregular atomic arrangement in the third indirect transition type semiconductor portion 13 and the third region having an irregular atomic arrangement in the fourth indirect transition type semiconductor portion 14 are put in contact with each other. Via the bonding process, the fourth indirect transition type semiconductor portion 14 having a low p-type impurity concentration can be formed on the third indirect transition type semiconductor portion 13 having a high p-type impurity concentration formed via ion implantation, without intentionally applying heat.

Subsequently, as illustrated in FIG. 6E, the fifth indirect transition type semiconductor portion 25 may be thinned. The method may be mechanical polishing, chemical mechanical polishing, etching, or the like. For example, the thickness of the fifth indirect transition type semiconductor portion 15 after the thickness is reduced is controlled to be in a range from 1 μm to 10 μm. In this manner, the layered structure 300 is obtained. For example, in FIG. 6E, the p-type Si substrate is polished to have a predetermined thickness (for example, 2 μm) to form the fifth indirect transition type semiconductor portion 15. In this manner, the layered structure 300 is obtained.

### Process of Forming Ridge

FIG. 6F illustrates an XZ cross-sectional configuration orthogonal to the resonance direction (Y direction). In FIG. 6F, the p-side electrode 17 is formed on the top surface of the fifth indirect transition type semiconductor portion 15 by a lift-off method or the like. After that, the ridge 20A (see FIG. 2) is formed by etching from the top surface of the fifth indirect transition type semiconductor portion 15 to partway through the fourth indirect transition type semiconductor portion 14. Subsequently, the protective film 18 is formed exposing the top surface of the electrode 17 and covering the lateral surface of the ridge and the top surface of the fourth indirect transition type semiconductor portion 14. The n-side electrode 16 may be formed of, for example, a Ti/Pt/Au film. The p-type electrode 17 may be formed of a Cr/Pt film. The protective film 18 may be formed of SiO₂, SiN, SiON, Al₂O₃, or the like. In a case in which DPP annealing is not performed in the process of forming the third indirect transition type semiconductor portion 13 illustrated in FIG. 6B, the n-side electrode 16 is formed on the back surface of the first indirect transition type semiconductor portion 11.

This concludes the description of a method for manufacturing a semiconductor optical element. In the case of forming the periodic grooves 201 as described with reference to FIGS. 5A, 5B, and 5C, the grooves 201 are formed at predetermined intervals in the process of forming the first structure 100 and/or the process of forming the second structure 200. The grooves 201 can be formed by patterning an object to be processed using a mask formed by electron beam lithography and then performing dry etching.

### Modified Examples

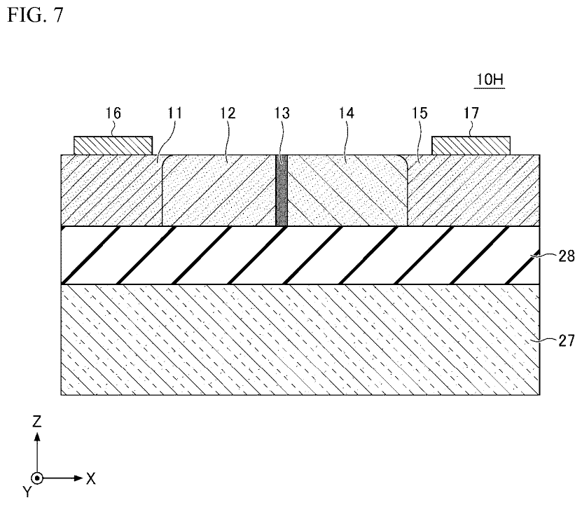

FIG. 7 is a schematic diagram illustrating a semiconductor optical element 10H, which is another modified example of the semiconductor optical element 10. In the semiconductor optical element 10H, the first indirect transition type semiconductor portion 11, the second indirect transition type semiconductor portion 12, the third indirect transition type semiconductor portion 13, the fourth indirect transition type semiconductor portion 14, and the fifth indirect transition type semiconductor portion 15 are arranged in this order from the left of the schematic diagram in a direction horizontal to a substrate 27, on an insulating layer 28 on the substrate 27. The light-emission direction is the Y direction.

The first indirect transition type semiconductor portion 11 includes the first conductivity type impurity at the first concentration. The second indirect transition type semiconductor portion 12 includes the first conductivity type impurity at the second concentration lower than the first concentration. The third indirect transition type semiconductor portion 13 includes the second conductivity type impurity at the third concentration. The fourth indirect transition type semiconductor portion 14 includes the second conductivity type impurity at the fourth concentration lower than the third concentration. The fifth indirect transition type semiconductor portion 15 includes the second conductivity type impurity at the fifth concentration higher than the fourth concentration. In this manner, a semiconductor optical element that efficiently emits light is obtained.

The third indirect transition type semiconductor portion 13 and the fourth indirect transition type semiconductor portion 14 are in contact with each other. The electrode 16 is provided on the first indirect transition type semiconductor portion 11, and the electrode 17 is provided on the fifth indirect transition type semiconductor portion 15. When a current is applied from the first indirect transition type semiconductor portion 11 to the fifth indirect transition type semiconductor portion 15 in the X direction by the electrodes 16 and 17 under light irradiation, DPPs are generated at the interface between the third indirect transition type semiconductor portion 13 and the fourth indirect transition type semiconductor portion 14, and light emission of a predetermined wavelength is obtained.

The configuration in FIG. 7 may be formed by forming an indirect transition type semiconductor layer of Si or the like on the insulating layer 28 on the substrate 27 and implanting impurities using a mask formed by a typical photolithography method. Alternatively, the layered structure 300 obtained as illustrated in FIG. 6E may be sliced parallel to the layering direction and provided on the insulating layer 28.

### Application Example

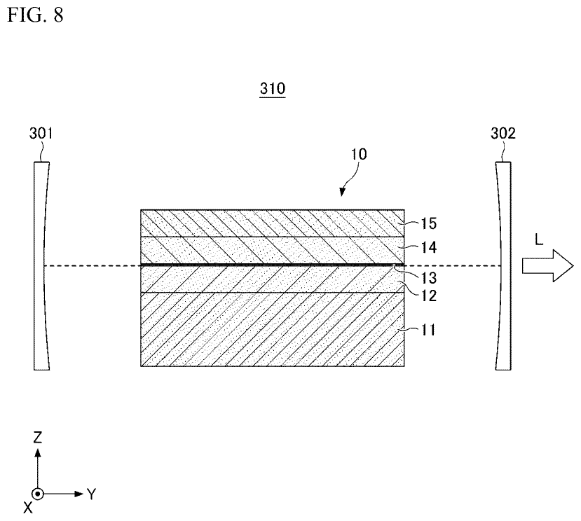

FIG. 8 is a schematic diagram of a light source device 310 using the semiconductor optical element 10. The light source device 310 includes a first mirror 301, a second mirror 302, and the semiconductor optical element 10 disposed between the first mirror 301 and the second mirror 302. In this manner, an external resonator is obtained. The first mirror 301 and the second mirror 302 constitute the external resonator, and light generated by the semiconductor optical element 10 passes through the second indirect transition type semiconductor portion 12, the third indirect transition type semiconductor portion 13, and the fourth indirect transition type semiconductor portion 14 serving as a core, travels back and forth between the first mirror 301 and the second mirror 302, is amplified, and is output from one of the mirrors (for example, the second mirror 302). Although omitted in FIG. 8 for the sake of convenience, electrodes may be provided in the semiconductor optical element 10 as illustrated in FIGS. 2 and 3 and the semiconductor optical element 10 may be driven by current injection. Alternatively, optical excitation may be performed using an external light source without providing electrodes. An anti-reflection film may be formed at the end surface of the semiconductor optical element 10 facing the first mirror 301 and the end surface of the semiconductor optical element 10 facing the second mirror 302. The distance between the first mirror 301 and the second mirror 302 is set to a multiple of the oscillation wavelength.

Instead of using spatially independent optical elements as the first mirror 301 and the second mirror 302, a diffraction grating mirror or a ring mirror formed of a Si wire waveguide on a Si substrate may be used. In this case, the semiconductor optical element 10 may be formed on the Si substrate, and a highly reflective film may be provided at one of the end surfaces orthogonal to the resonance direction (optical axis) of the semiconductor optical element 10, and this highly reflective film may be used as one of the mirrors forming an external resonator. A current source for current application and a laser element for light irradiation may be incorporated into the light source device 310.

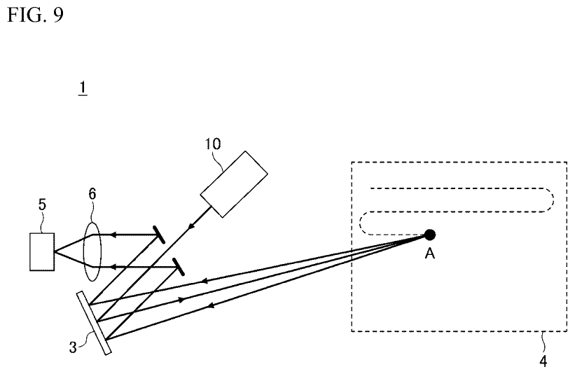

FIG. 9 is a schematic diagram of a measurement device 1 using the semiconductor optical element 10. The measurement device 1 includes the semiconductor optical element 10 and a light-receiving element 5 that detects reflected light of light emitted from the semiconductor optical element 10. The measurement device 1 also includes a scanning mirror 3 and a condenser lens 6.

The light emitted from the semiconductor optical element 10 is scanned by the scanning mirror 3 to a distance measuring region 4 where a target object exists. The return light reflected at each scanning point A on the target object is reflected by the scanning mirror 3, guided to the condenser lens 6 using an additional optical element as necessary, and made incident on the light-receiving element 5. The distance to the target object is measured by the time of flight (TOF) method based on time of flight from light emission from the semiconductor optical element 10 to detection by the light-receiving element 5. By collecting the data of the scanning points A, the target object can be three-dimensionally captured.

The examples described above of the semiconductor optical element and the method for manufacturing the semiconductor optical element according to embodiments used specific configuration examples, but the present disclosure is not limited to the configuration examples described above. The configuration examples and modified examples described above may be combined with each other. The grooves 201 for wavelength selection may be provided in any of the configurations of the semiconductor optical elements 10A and 10B. Note that the semiconductor optical element may spontaneously undergo DPP annealing while being driven. In the embodiments, the principle of light emission of the semiconductor optical element has been described using DPP as an example. However, the principle of light emission is not limited to DPP. The principle of light emission of the semiconductor optical element may be, for example, light emission via an impurity level or light emission via a level derived from a defect or a dislocation.

In FIG. 6B, the energy of ion implantation when forming the p-type Si layer on the top surface of the second indirect transition type semiconductor portion 12 is not limited to the above-described level, and can be appropriately set in accordance with the target thickness of the third indirect transition type semiconductor portion 13. The implantation energy does not need to be a single energy, and implantation may be performed sequentially with a plurality of implantation energies. The concentration distribution of the p-type impurity in the third indirect transition type semiconductor portion 13 may have a gradient from the interface with the fourth indirect transition type semiconductor portion 14 to the interface with the second indirect transition type semiconductor portion 12. It is desirable that the impurity elements are irregularly localized at the interface between the third indirect transition type semiconductor portion 13 and the second indirect transition type semiconductor portion 12. In any of the cases, a semiconductor optical element using an indirect transition type semiconductor and a method for manufacturing the semiconductor optical element are achieved.

1. A semiconductor optical element comprising, in a following order:
a first indirect transition type semiconductor portion including a first conductivity type impurity at a first concentration;
a second indirect transition type semiconductor portion including the first conductivity type impurity at a second concentration;
a third indirect transition type semiconductor portion including a second conductivity type impurity at a third concentration;
a fourth indirect transition type semiconductor portion including the second conductivity type impurity at a fourth concentration; and
a fifth indirect transition type semiconductor portion including the second conductivity type impurity at a fifth concentration, wherein:
the third indirect transition type semiconductor portion and the fourth indirect transition type semiconductor portion are in contact with each other,
the first concentration is higher than the second concentration,
the third concentration is higher than the fourth concentration, and
the fifth concentration is higher than the fourth concentration.

2. The semiconductor optical element according to claim 1, wherein a thickness of the third indirect transition type semiconductor portion is in a range from 10 nm to 1500 nm.

3. The semiconductor optical element according to claim 1, wherein the third concentration is in a range from 10 times to 1000 times the fourth concentration.

4. The semiconductor optical element according to claim 2, wherein the third concentration is in a range from 10 times to 1000 times the fourth concentration.

5. The semiconductor optical element according to claim 1, wherein:
the first conductivity type is n-type,
the second conductivity type is p-type, and
the first concentration is higher than the fifth concentration.

6. The semiconductor optical element according to claim 1, wherein the semiconductor optical element is configured to emit light with a peak wavelength in a range from 1100 nm to 4000 nm.

7. The semiconductor optical element according to claim 2, wherein the semiconductor optical element is configured to emit light with a peak wavelength in a range from 1100 nm to 4000 nm.

8. The semiconductor optical element according to claim 3, wherein the semiconductor optical element is configured to emit light with a peak wavelength in a range from 1100 nm to 4000 nm.

9. The semiconductor optical element according to claim 1, comprising:
a ridge in which at least a part of the fourth indirect transition type semiconductor portion and the fifth indirect transition type semiconductor portion are layered, wherein:
the third indirect transition type semiconductor portion is located below the ridge.

10. The semiconductor optical element according to claim 8, comprising:
a ridge in which at least a part of the fourth indirect transition type semiconductor portion and the fifth indirect transition type semiconductor portion are layered, wherein:
the third indirect transition type semiconductor portion is located below the ridge.

11. The semiconductor optical element according to claim 9, wherein a width of the ridge increases from a side where the fifth indirect transition type semiconductor portion is located toward the first indirect transition type semiconductor portion.

12. The semiconductor optical element according to claim 1, wherein:
a plurality of grooves or a plurality of voids are located at intervals in at least one of the first indirect transition type semiconductor portion or the second indirect transition type semiconductor portion, and
the plurality of grooves or the plurality of voids are arranged in at least a first direction that is aligned with a resonance direction of the semiconductor optical element.

13. The semiconductor optical element according to claim 9, wherein:
a plurality of grooves or a plurality of voids are located at intervals in at least one of the first indirect transition type semiconductor portion or the second indirect transition type semiconductor portion, and
the plurality of grooves or the plurality of voids are arranged in at least a first direction that is aligned with a resonance direction of the semiconductor optical element.

14. The semiconductor optical element according to claim 1, wherein:
the third indirect transition type semiconductor portion comprises a first region and a second region,
the fourth indirect transition type semiconductor portion comprises a third region and a fourth region,
the third indirect transition type semiconductor portion and the fourth indirect transition type semiconductor portion are in contact with each other at the first region and the third region,
an atomic arrangement is more irregular in the first region than in the second region, and
an atomic arrangement is more irregular in the third region than in the fourth region.

15. The semiconductor optical element according to claim 13, wherein:
the third indirect transition type semiconductor portion comprises a first region and a second region,
the fourth indirect transition type semiconductor portion comprises a third region and a fourth region,
the third indirect transition type semiconductor portion and the fourth indirect transition type semiconductor portion are in contact with each other at the first region and the third region,
an atomic arrangement is more irregular in the first region than in the second region, and
an atomic arrangement is more irregular in the third region than in the fourth region.

16. A measurement device comprising:
the semiconductor optical element according to claim 1; and
a light-receiving element configured to detect reflected light of light emitted from the semiconductor optical element.

17. A light source device comprising:
a first mirror;
a second mirror; and
the semiconductor optical element according to claim 1 disposed between the first mirror and the second mirror.

18. A method for manufacturing a semiconductor optical element, comprising:
preparing a first structure comprising:
a first indirect transition type semiconductor portion including a first conductivity type impurity at a first concentration,
a second indirect transition type semiconductor portion including the first conductivity type impurity at a second concentration lower than the first concentration, the second indirect transition type semiconductor portion being provided on the first indirect transition type semiconductor portion, and
a third indirect transition type semiconductor portion including a second conductivity type impurity at a third concentration, the third indirect transition type semiconductor portion being provided on the second indirect transition type semiconductor portion;
preparing a second structure comprising:
a fourth indirect transition type semiconductor portion including the second conductivity type impurity at a fourth concentration, and
a fifth indirect transition type semiconductor portion including the second conductivity type impurity at a fifth concentration, the fourth concentration being lower than the third concentration and the fifth concentration, wherein:
the fourth indirect transition type semiconductor portion is provided on the fifth indirect transition type semiconductor portion; and
directly bonding the third indirect transition type semiconductor portion and the fourth indirect transition type semiconductor portion with the third indirect transition type semiconductor portion of the first structure and the fourth indirect transition type semiconductor portion of the second structure facing each other.

19. The method for manufacturing a semiconductor optical element, according to claim 18, wherein the third indirect transition type semiconductor portion is obtained via ion implantation at a surface of the second indirect transition type semiconductor portion opposite a surface of the second indirect transition type semiconductor portion where the first indirect transition type semiconductor portion is provided.
